(19) United States
(12) Patent Application Publication
(10) Pub. No.: US 2007/0051998 A1
(43) Pub. Date: Mar. 8, 2007

(54) Semiconductor memory device with dielectric structure and method for fabricating the same

(76) Inventors: Deok-Sin Kil, Kyoungki-do (KR); Kwon Hong, Kyoungki-do (KR); Seung-Jin Yeom, Kyoungki-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/387,563

(22) Filed: Mar. 22, 2006

(30) Foreign Application Priority Data
Sep. 8, 2005 (KR) 2005-0083692

(51) Int. Cl. H01L 29/94

(52) U.S. Cl. 257/310; 257/E27.104

(57) ABSTRACT

A semiconductor memory device with a dielectric structure and a method for fabricating the same are provided. The dielectric structure includes: a first dielectric layer having a dielectric constant of approximately 25 or higher; a second dielectric layer including a material having a crystallization rate lower than the first dielectric layer and formed over the first dielectric layer; and a third dielectric layer including a material substantially identical to that of the first dielectric layer and formed over the second dielectric layer.

### FIELD OF THE INVENTION

The present invention relates to a semiconductor memory device and a method for fabricating the same; and, more particularly, to a semiconductor memory device provided with a dielectric layer and a method for fabricating the same.

### DESCRIPTION OF RELATED ARTS

For a semiconductor memory device, e.g., a DRAM device, the size of a memory cell region for storing 1 bit has become smaller as the degree of integration has increased. Herein, 1 bit is the basic unit for memory information. However, the size of a capacitor cannot be reduced in proportion to the memory cell region reduction. This result is because a dielectric capacity above a certain level is required for each of the unit cells to prevent soft errors and maintain stable operations. Thus, researches for maintaining the capacity of the capacitor within the limited cell region above a certain level are being demanded. Such researches have progressed in three different ways. The first one is a method for reducing the thickness of a dielectric layer, the second one is a method for increasing an active region of a capacitor, and the third one is a method for utilizing a dielectric layer with a high relative dielectric constant.

Below, the method for utilizing a dielectric layer with a high relative dielectric constant is described in detail. A mainly used dielectric layer in a conventional capacitor includes a silicon dioxide (SiO₂) thin layer, and a nitride-oxide (NO) thin layer and an oxide-nitride-oxide (ONO) thin layer both using silicon nitride (Si₃N₄) with a dielectric constant two times higher than the one of the SiO₂ thin layer.

However, the SiO₂, NO and ONO thin layers have low dielectric constants. Even if the thickness of the dielectric layer is reduced or the surface region of the dielectric layer is enlarged, there still exists a limitation in increasing the dielectric constant. Thus, using a material with a high dielectric constant is becoming essentially required.

As a result, materials such as hafnium oxide (HfO₂), silicon oxynitride (SiON), aluminum oxide (Al₂O₃), and strontium titanate (SrTiO₃) are introduced to replace the conventional dielectric layer in a highly-integrated DRAM. For a SiON or Al₂O₃ layer, leakage current increases rapidly as the thickness decreases. Thus, it is difficult to form a dielectric layer using SiON or Al₂O₃ in a thickness of approximately 40 Å or below.

On the other hand, for a SrTiO₃ layer with a high dielectric constant (ε), wherein e is in a range of approximately 200, the high dielectric constant and a superior leakage current characteristic can be secured when formed in a thickness of approximately 200 Å or above. A dielectric layer of a capacitor applied in a micro device under 100 nm is generally required to be formed in a thickness of approximately 100 Å or under. However, if the SrTiO₃ layer is formed in a thickness of approximately 100 Å or under, the dielectric constant and the leakage current characteristic are rapidly deteriorated.

Although a HfO₂ layer has a high dielectric constant of 25, it may be difficult to apply the HfO₂ layer solely because the HfO₂ layer has a heat stability limitation due to a low crystallization temperature, resulting in high leakage current. To overcome such limitation, a structure wherein an Al₂O₃ layer is formed on the HfO₂ layer has been introduced conventionally. However, such structure generates a dielectric capacity loss due to the low dielectric constant (ε) of Al₂O₃, (i.e., ε=9).

### SUMMARY OF THE INVENTION

It is, therefore, an object of the present invention to provide a dielectric layer capable of securing a dielectric capacity and improving a leakage current characteristic, and a method for fabricating the same.

Another object of the present invention is to provide a semiconductor memory device including the dielectric layer, capable of securing a dielectric constant and improving a leakage current characteristic, and a method for fabricating the same.

In accordance with an aspect of the present invention, there is provided a dielectric structure, including: a first dielectric layer having a dielectric constant of approximately 25 or higher; a second dielectric layer including a material having a crystallization rate lower than the first dielectric layer and formed over the first dielectric layer; and a third dielectric layer including a material substantially identical to that of the first dielectric layer and formed over the second dielectric layer.

In accordance with another aspect of the present invention, there is provided a method for forming a dielectric structure, including: forming a first dielectric layer having a dielectric constant of approximately 25 or higher; forming a second dielectric layer over the first dielectric layer, the second dielectric layer having a crystallization rate lower than the first dielectric layer; and forming a third dielectric layer over the second dielectric layer, the third dielectric layer including a material substantially identical to that of the first dielectric layer.

In accordance with still another aspect of the present invention, there is provided a semiconductor memory device, including: a substrate on which a bottom electrode is formed; a dielectric structure formed over the bottom electrode, wherein the dielectric structure includes: a first dielectric layer having a dielectric constant of approximately 25 or higher; a second dielectric layer including a material having a crystallization rate lower than the first dielectric layer and formed over the first dielectric layer; and a third dielectric layer including a material substantially identical to that of the first dielectric layer and formed over the second dielectric layer; and an upper electrode formed over the dielectric structure.

In accordance with still another aspect of the present invention, there is provided a method for fabricating a semiconductor memory device, including: preparing a substrate whereon a bottom electrode is formed; forming a dielectric structure over the bottom electrode, wherein the forming of the dielectric structure includes: forming a first dielectric layer having a dielectric constant of approximately 25 or higher; forming a second dielectric layer over the first dielectric layer, the second dielectric layer having a crystallization rate lower than the first dielectric layer; and forming a third dielectric layer over the second dielectric layer, the third dielectric layer having a material substantially identical to that of the first dielectric layer; and forming an upper electrode over the dielectric structure.

In accordance with still another aspect of the present invention, there is provided a semiconductor memory device, including: a gate insulation layer formed over a substrate; a floating gate formed over the gate insulation layer; a dielectric structure formed over the floating gate, wherein the dielectric structure includes: a first dielectric layer having a dielectric constant of approximately 25 or higher; a second dielectric layer including a material having a crystallization rate lower than the first dielectric layer and formed over the first dielectric layer; and a third dielectric layer including a material substantially identical to that of the first dielectric layer and formed over the second dielectric layer; and a control gate formed over the dielectric structure.

In accordance with further aspect of the present invention, there is provided a method for fabricating a semiconductor memory device, including: forming a gate insulation layer over a substrate; forming a floating gate over the gate insulation layer; forming a dielectric structure over the floating gate, wherein the forming of the dielectric structure includes: forming a first dielectric layer having a dielectric constant of 25 or higher; forming a second dielectric layer over the first dielectric layer, the second dielectric layer having a crystallization rate lower than the first dielectric layer; and forming a third dielectric layer over the second dielectric layer, the third dielectric layer having a material substantially identical to that of the first dielectric layer; and forming a control gate over the dielectric structure.

### BRIEF DESCRIPTION OF THE DRAWINGS

The above and other objects and features of the present invention will become better understood with respect to the following description of the specific embodiments given in conjunction with the accompanying drawings, in which:

FIG. 1 is a cross-sectional view illustrating a dielectric structure in accordance with a first embodiment of the present invention;

FIG. 2 is a graph illustrating a surface roughness characteristic of a zirconium dioxide (ZrO₂) layer depending on different thicknesses;

FIG. 3 is a semiconductor electron microscope (SEM) view illustrating a leakage current characteristic of a crystalline ZrO₂ layer;

FIG. 4 is a micrographic view illustrating a surface roughness of a single ZrO₂ layer formed in a thickness of approximately 80 Å;

FIG. 5 is a micrographic view illustrating a surface roughness of a dielectric structure formed in a stacked structure of ZrO₂ (40 Å)/aluminum oxide (Al₂O₃) (5 Å)/ZrO₂ (40 Å) in accordance with the first embodiment of the present invention;

FIG. 6 is a flow-chart illustrating a method for forming the dielectric structure shown in FIG. 1;

FIG. 7 is a cross-sectional view illustrating a capacitor in accordance with a second embodiment of the present invention; and

FIG. 8 is a cross-sectional view illustrating a non-volatile memory device in accordance with a third embodiment of the present invention.

### DETAILED DESCRIPTION OF THE INVENTION

A semiconductor memory device with a dielectric structure and a method for fabricating the same in accordance with specific embodiments of the present invention will be described in detail with reference to the accompanying drawings. Also, regarding the drawings, the illustrated thickness of layers and regions are exaggerated for definitude. When a first layer is referred to as being on a second layer or “on” a substrate, it could mean that the first layer is formed right on the second layer or the substrate, or it could also mean that a third layer may exit between the first layer and the substrate. Furthermore, identical reference numerals through out the specific embodiments of the present invention represent identical or like elements.

Hereinafter, a first embodiment of the present invention will be described in detail.

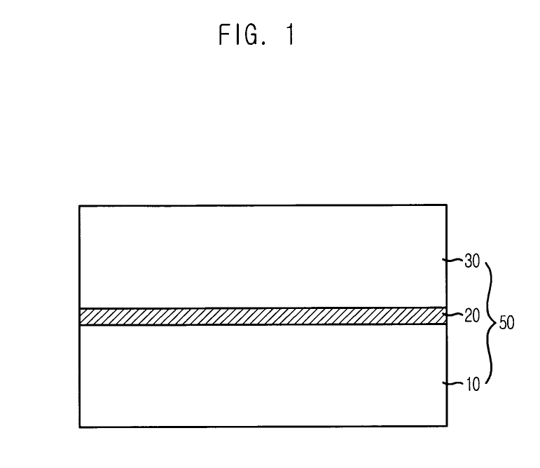

FIG. 1 is a cross-sectional view illustrating a dielectric structure in accordance with the first embodiment of the present invention.

As shown in FIG. 1, a dielectric structure 50 includes: a first dielectric layer 10 having a dielectric constant of 25 or higher; a second dielectric layer 20 including a material having a crystallization rate lower than the first dielectric layer 10; and a third dielectric layer 30 including a material substantially identical to the first dielectric layer 10. Herein, the second dielectric layer 20 is formed on the first dielectric layer 10, and the third dielectric layer 30 is formed on the second dielectric layer 20. Herein, the crystallization rate refers to the probability of a layer to become crystallized by various external factors including temperature. Preferably, the crystallization rate described in the specific embodiments of the present invention refers to the probability of a layer to become crystallized at a substantially identical temperature.

When a layer is crystallized, leakage current increases rapidly through a grain boundary of the layer. Thus, both of the first dielectric layer 10 and the third dielectric layer 30 are formed in a predetermined thickness that does not allow crystallization of the layers in the first embodiment of the present invention. For example, each of the first dielectric layer 10 and the third dielectric layer 30 is formed in a thickness ranging from approximately 10 Å to approximately 70 Å.

At this time, a total thickness of the first, second, and third dielectric layer 10, 20 and 30 ranges from approximately 70 Å to approximately 100 Å. Each of the first dielectric layer 10 and the third dielectric layer 30 is formed by employing one selected from the group consisting of zirconium dioxide (ZrO₂), hafnium oxide (HfO₂), lanthanum oxide (La₂O₃), and tantalum oxide (Ta₂O₅). Preferably, each of the first dielectric layer 10 and the third dielectric layer 30 is formed by employing ZrO₂ in a thickness ranging from approximately 35 Å to 45 Å.

Also, the second dielectric layer 20 is formed with a material that has a lower dielectric constant than the first dielectric layer 10 or a material crystallized at a temperature of approximately 900° C. or higher. For example, the second dielectric layer 20 is formed by one selected form the group consisting of aluminum oxide (Al₂O₃), silicon dioxide (SiO₂), and Ta₂O₅. Preferably, the second dielectric layer 20 is formed in a thickness ranging from approximately 3 Å to 10 Å.

Consequently, the dielectric structure 50 has a stacked structure of three layers in accordance with the first embodiment of the present invention. The three layers refer to the first dielectric layer 10 and the third dielectric layer 30, both including the substantially identical material, and the second dielectric layer 20 including a material different to that of the first dielectric layer 10 and the third dielectric layer 30, formed between the first dielectric layer 10 and the third dielectric layer 30. For example, the dielectric structure 50 has a structure of either ZrO₂/Al₂O₃/ZrO₂ or HfO₂/Al₂O₃/HfO₂. Most preferably, the dielectric structure 50 has a stacked structure of ZrO₂/Al₂O₃/ZrO₂. This result is because a band gap characteristic of HfO₂ is inferior to ZrO₂, and thus, a leakage current characteristic is deteriorated in HfO₂. Referring to Table 1 below, a band gap energy level of HfO₂ is 5.7, lower than a bank gap energy level of ZrO₂ of 7.8.

TABLE 1

| | Dielectric | Band gap | |
|---|---|---|---|
| Material | constant (k) | Eg(eV) | Crystal structure(s) |
| SiO₂ | 3.9 | 8.9 | Amorphous |
| Si₃N₄ | 7 | 5.1 | Amorphous |
| Al₂O₃ | 9 | 8.7 | Amorphous |
| Y₂O₃ | 15 | 5.6 | Cubical |
| La₂O₃ | 30 | 4.3 | Hexagonal, Cubical |
| Ta₂O₅ | 26 | 4.5 | Orthorhombic |
| TiO₂ | 80 | 3.5 | Tetragonal |
| | | | (rutile, anatase) |
| HfO₂ | 25 | 5.7 | Monoclinic, Orthorhombic, |
| | | | Cubical |
| ZrO₂ | 25 | 7.8 | Monoclinic, Orthorhombic, |
| | | | Cubical |

Herein, ZrO₂ is formed in a predetermined thickness that does not allow crystallization of ZrO₂, i.e., in a thickness of approximately 40 Å, and Al₂O₃ is formed substantially thinner than ZrO₂, i.e., in a thickness of approximately 5 Å.

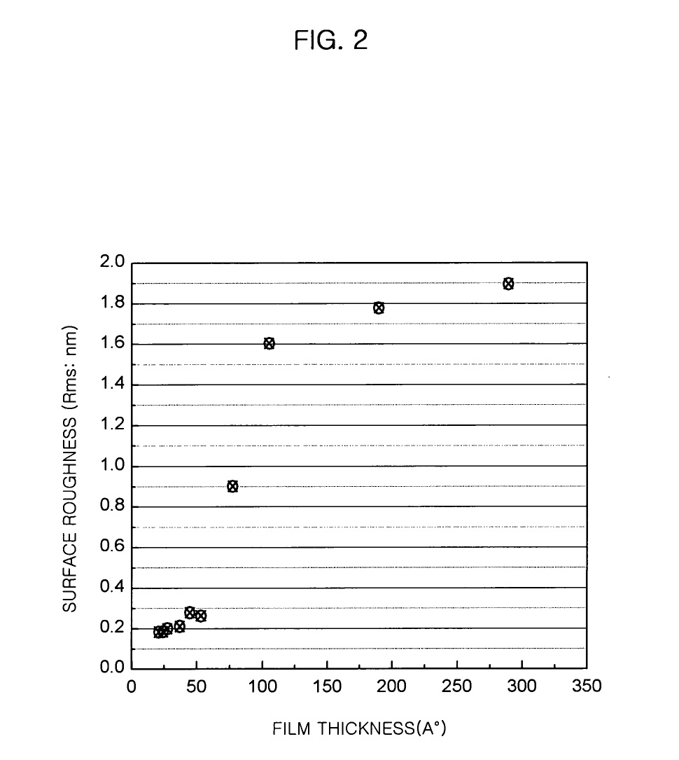

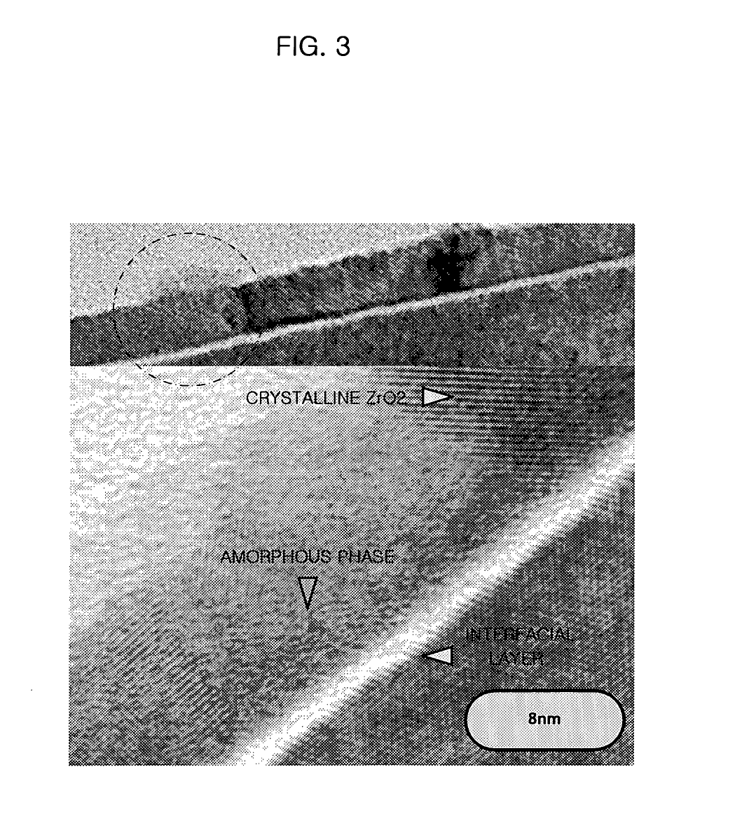

For reference, a high-k dielectric layer such as a ZrO₂ layer is crystallized at a certain temperature. As shown in FIG. 2, especially, a surface roughness of ZrO₂ rapidly increases when formed in a thickness of approximately 50 Å or higher. Such increase of the surface roughness is caused by crystallization of ZrO₂. This result shows that leakage current increases when ZrO₂ is formed in a thickness of approximately 50 Å or higher. That is, as shown in FIG. 3, the leakage current flows along a partially crystallized grain boundary of ZrO₂.

Therefore, in the first embodiment of the present invention, each of the first dielectric layer 10 and the third dielectric layer 30 is formed in a predetermined thickness that does not allow crystallization of the layers, i.e., in a thickness ranging from approximately 35 to approximately 45 Å, and the second dielectric layer 20 including a material different to that of the first dielectric layer 10 and the third dielectric layer 30, is formed between the first dielectric layer 10 and the third dielectric layer 30. Herein, the second dielectric layer 20 is in a non-crystallized state. Through these processes, the dielectric structure 50 is not crystallized even during a subsequent thermal process. Therefore, a leakage current characteristic of the dielectric structure 50 can be improved.

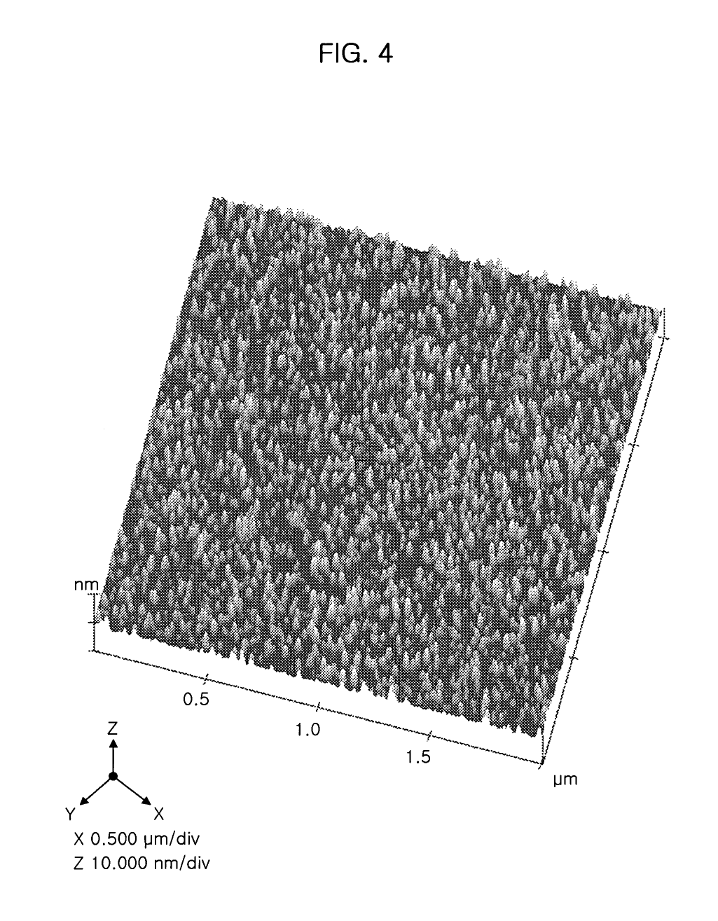

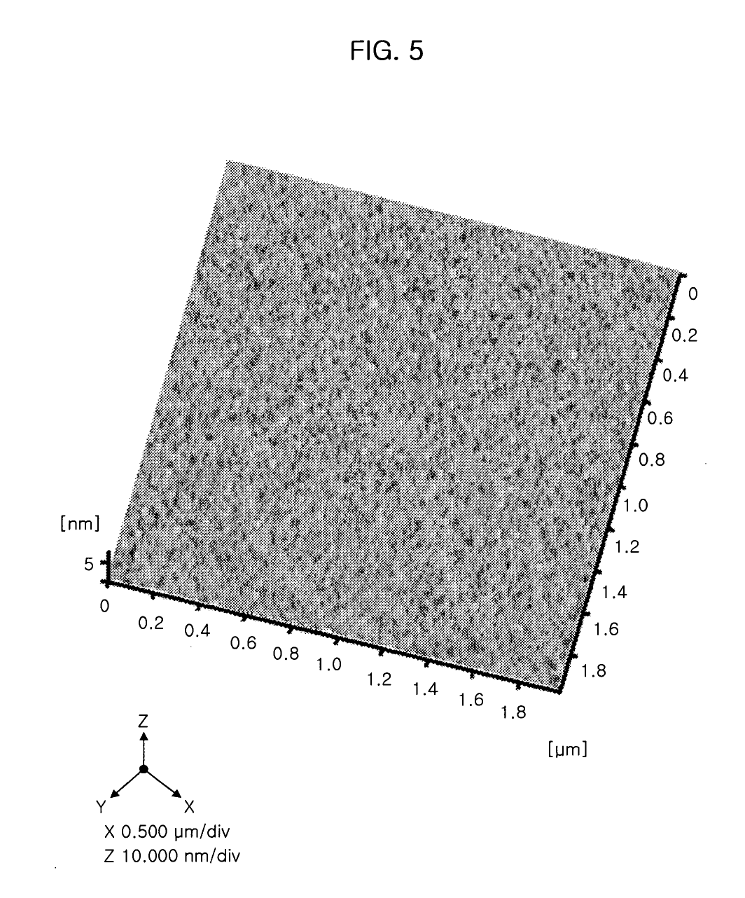

FIG. 4 is a micrographic view illustrating a surface roughness of a single ZrO₂ layer formed in a thickness of approximately 80 Å. FIG. 5 is a micrographic view illustrating a surface roughness of a dielectric structure having a stacked structure of ZrO₂/Al₂O₃/ZrO₂, each formed in a thickness of 40 Å, 5 Å, and 40 Å, respectively, in accordance with the first embodiment of the present invention. Thus, the leakage current of the dielectric structure 50 can be reduced overall.

Hereinafter, a method for fabricating the dielectric structure 50 shown in FIG. 1 is briefly described. The method in accordance with the first embodiment of the present invention includes: forming the first dielectric layer 10 having a dielectric constant of 25 or higher; forming the second dielectric layer 20 having a crystallization rate lower than the first dielectric layer 10 at a substantially identical temperature; and forming the third dielectric layer 30 including a material substantially identical to the first dielectric layer 10. Herein, the second dielectric layer 20 is formed on the first dielectric layer 10, and the third dielectric layer 30 is formed on the second dielectric layer 20.

The first dielectric layer 10 and the third dielectric layer 30 are each formed in a predetermined thickness that does not allow crystallization of the layers. Preferably, each of the first dielectric layer 10 and the third dielectric layer 30 is formed in a thickness ranging from approximately 10 Å to approximately 70 Å.

Also, each of the first dielectric layer 10 and the third dielectric layer 30 is formed by employing one selected from the group consisting of ZrO₂, HfO₂, La₂O₃, and Ta₂O₅. Preferably, each of the first dielectric layer 10 and the third dielectric layer 30 is formed by employing ZrO₂ in a thickness ranging from approximately 35 Å to approximately 45 Å.

Furthermore, each of the first dielectric layer 10 and the third dielectric layer 30 is formed by employing one of an atomic layer deposition (ALD) method and a chemical vapor deposition (CVD) method. Herein, when each of the first dielectric layer 10 and the third dielectric layer 30 is formed by employing the ALD method, one of water (H₂O), ozone (O₃), and oxygen plasma is used as an oxidation reaction gas, and one of nitrogen (N₂) and argon (Ar) is used as a purge gas for purging non-reacted gas.

The second dielectric layer 20 is formed with a material that has a dielectric constant lower than the first dielectric layer 10 or a material crystallized at a temperature of approximately 900° C. or higher. The second dielectric layer 20 is formed by employing one selected from the group consisting of Al₂O₃, SiO₂, and Ta₂O₅. Preferably, the second dielectric layer 20 is formed by employing Al₂O₃ in a thickness ranging from approximately 3 Å to approximately 10 Å.

Moreover, the second dielectric layer 20 is formed by employing an ALD method. Herein, when the second dielectric layer 20 is formed by employing the ALD method, one of H₂O, O₃, and oxygen plasma is used as an oxidation reaction gas, and one of N₂ and Ar is used as a purge gas for purging non-reacted gas.

The above formation of the first dielectric layer 10, the second dielectric layer 20, and the third dielectric layer 30 can be either: performed at the same chamber, i.e., in-situ; or performed at two different chambers, one chamber for forming the first dielectric layer 10 and the third dielectric layer 30, and the other chamber for forming the second dielectric layer 20. When forming the first dielectric layer 10, the second dielectric layer 20, and the third dielectric layer 30 at the same chamber, the process is performed at a temperature ranging from approximately 200° C. to approximately 350° C.

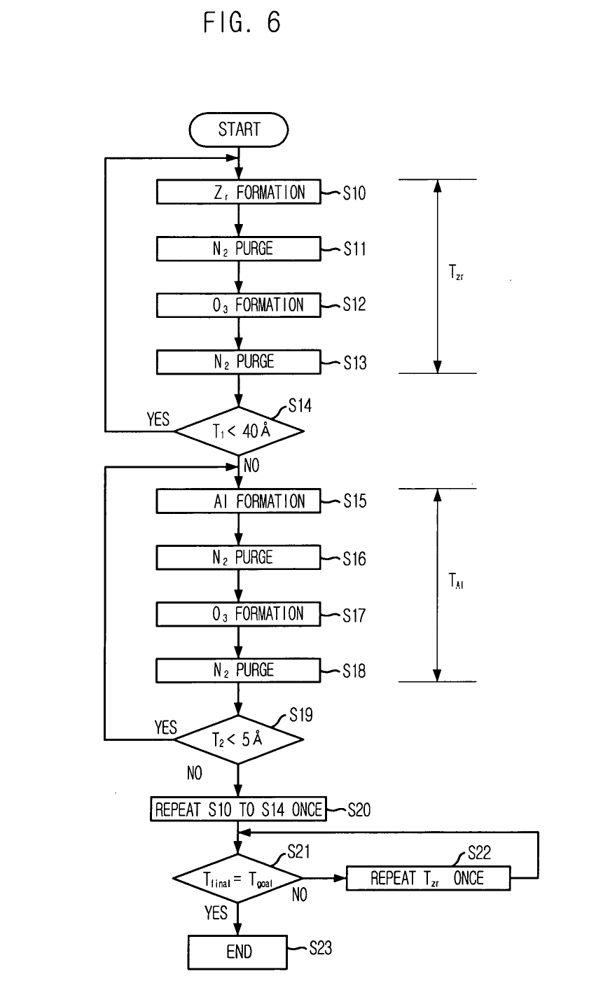

FIG. 6 is a flow-chart illustrating a method for fabricating a dielectric structure in accordance with the first embodiment of the present invention. Hereinafter, the method for fabricating the dielectric structure will be described in more detail, based on the flow-chart. Herein, only the method for forming a dielectric structure having an ideal stacked structure of ZrO₂/Al₂O₃/ZrO₂ (refer to FIG. 5) will be described for the convenience of description.

As shown in FIG. 6, ZrO₂ layer formation is performed to form a first dielectric layer. The ZrO₂ layer formation is as follows. A zirconium (Zr) source gas selected from the group consisting of Zr[N(CH₃)₂]₄, Zr[N(C₂H₅)(CH₃)]₄, Zr[N(C₂H₅)₂]₄, Zr(TMHD)₄, Zr(OiC₃H₇)₃(TMHD), Zr(OtBu)₄, and Zr(OtBu)(C₂H₅CH₃)₃ is implanted inside a chamber of an ALD equipment to deposit Zr on a wafer (not shown) at step S10. Herein, a temperature ranging from approximately 200° C. to approximately 350° C. is maintained inside the chamber. Subsequently, N₂ (or Ar) gas is implanted inside the chamber to purge the remaining Zr source gas, which did not become deposited, out the chamber at step S11. Next, O₃ (or one of H₂O and oxygen plasma) is implanted inside the chamber to oxidize the deposited Zr, thereby forming a ZrO₂ layer as the first dielectric layer at step S12. Then, N₂ gas is implanted inside the chamber once more to purge any non-reacted O₃ at step S13.

The steps S10 to S13 are performed as one cycle T_{zr}, and the cycle T_{zr} is repeatedly performed until a thickness T₁ of the ZrO₂ layer reaches approximately 40 Å. Herein, the reason for limiting the thickness T₁ of the ZrO₂ layer to approximately 40 Å is to prevent crystallization of the ZrO₂ layer. For example, it is easy for a ZrO₂ layer to become crystallized when formed in a thickness of approximately 50 Å or thicker. During one cycle T_{zr}, the thickness T₁ of the ZrO₂ layer reaches approximately 1 Å. Therefore, the ZrO₂ layer can be formed in a thickness nearing approximately 40 Å by repeating the cycle T_{zr} approximately 40 times.

Subsequently, an Al₂O₃ layer formation is performed to form a second dielectric layer. The Al₂O₃ layer formation is as follows. An Al(CH₃)₃ source gas is implanted inside the chamber to deposit aluminum (Al) on the ZrO₂ layer by in-situ at step S15. Herein, the step S15 can be performed using two different chambers, one for forming the ZrO₂ layer and the other one for forming the Al₂O₃ layer. Subsequently, N₂ (or Ar) gas is implanted inside the chamber to purge the remaining Al source gas, which did not become deposited, out the chamber at step S16. Next, O₃ (or one of H₂O and oxygen plasma) is implanted inside the chamber to oxidize the deposited Al, thereby forming an Al₂O₃ layer as the second dielectric layer at step S17. Then, N₂ gas is implanted inside the chamber to purge any non-reacted O₃ at step S18.

The steps S15 to S18 are performed as one cycle T_{A1}, and the cycle T_{A1} is repeatedly performed until a thickness T₂ of the Al₂O₃ layer reaches approximately 5 Å. During one cycle T_{A1}, the thickness T₂ of the Al₂O₃ layer reaches approximately 1 Å. Therefore, the Al₂O₃ layer can be formed in a thickness nearing approximately 5 Å by repeating the cycle T_{A1} approximately 5 times.

Furthermore, the steps S10 to S14 are performed one more time to form another ZrO₂ layer, identical to the first dielectric layer, as a third dielectric layer at step S20. Consequently, the latter ZrO₂ layer is formed in a thickness of approximately 40 Å.

Moreover, if a total thickness T_{final} of the ZrO₂/Al₂O₃/ZrO₂ structure is smaller than a goal thickness T_{goal}, then, the cycle T_{zr} for the ZrO₂ layer formation is repeatedly performed once at a time at step S22. Herein, the goal thickness T_{goal} refers to a predetermined thickness for securing a dielectric capacity. Step S21 and the step S22 are repeatedly performed until the total thickness T_{final} of the ZrO₂/Al₂O₃/ZrO₂ structure becomes substantially identical to the goal thickness T_{goal}. Herein, the goal thickness T_{goal} is approximately 80 Å, and thus, the step S22 is not repeated. In the first embodiment of the present invention, the dielectric structure is formed in the thickness of approximately 80 Å, and thus, the dielectric capacity of the dielectric structure can be secured.

Hereinafter, a second embodiment of the present invention is described in detail.

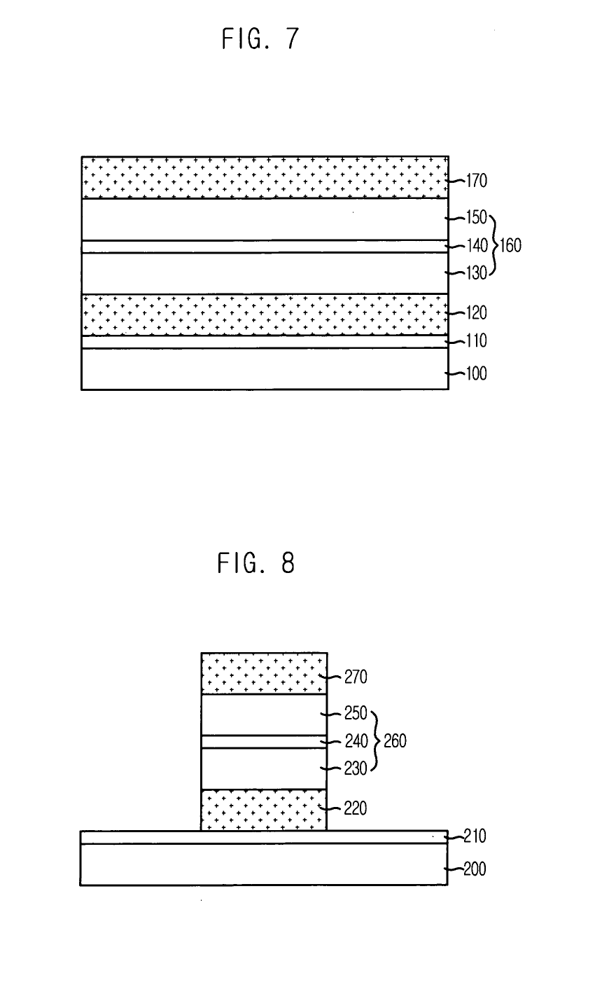

The dielectric structure in accordance with the first embodiment of the present invention can be generally applied in a capacitor of a dynamic random access memory (DRAM). FIG. 7 is a cross-sectional view illustrating a capacitor formed in accordance with the second embodiment of the present invention, wherein the second embodiment is an example whereto the first embodiment of the present invention is applied. Herein, a stack type capacitor is illustrated for the convenience of description. However, the stack type capacitor is one of many examples of application. The first embodiment of the present invention can be applied to a concave type or a cylinder type capacitor.

Referring to FIG. 7, the capacitor in accordance with the second embodiment of the present invention includes: a substrate 100 on which predetermined processes including transistor and bit lines formation are completed; an inter-layer dielectric (ILD) 110 formed over bit lines on the substrate 100; a bottom electrode 120 formed over the ILD 110; a dielectric structure 160 formed in accordance with the first embodiment of the present invention; and an upper electrode 170 formed over the dielectric structure 160.

Herein, the dielectric structure 160 includes a first dielectric layer 130 and a third dielectric layer 150, both formed with a substantially identical material, and a second dielectric layer 140 formed with a material different to that of the first dielectric layer 130 and the third dielectric layer 150. Herein, the second dielectric layer 140 is formed between the first dielectric layer 130 and the third dielectric layer 150. Since the dielectric structure 160 has a configuration substantially identical to that described in the first embodiment of the present invention, detailed descriptions with respect to configuration materials of the dielectric structure 160 are abridged herein.

Herein, the bottom electrode 120 is formed by employing one selected from the group consisting of doped polysilicon, titanium nitride (TiN), ruthenium (Ru), ruthenium dioxide (RuO₂), platinum (Pt), iridium (Ir), iridium dioxide (IrO₂), RuTiN, hafnium mononitride (HfN), and zirconium mononitride (ZrN).

Also, the upper electrode 170 is formed by employing one selected form the group consisting of doped polysilicon, TiN, Ru, RuO₂, Pt, Ir, IrO₂, and RuTiN.

Hereinafter, a method for forming the capacitor illustrated in FIG. 7 is described in detail.

The ILD 110 is formed over the substrate 100, transistors, and bit lines. At this time, the ILD 110 is formed by employing an oxide-based material. For example, the ILD 110 is formed by employing one selected from the group consisting of a high density plasma (HDP) oxide layer, a boro-phospho-silicate glass (BPSG) layer, a phosphosilicate glass (PSG) layer, a plasma enhanced tetraethyle orthosilicate (PETEOS) layer, a plasma enhanced chemical vapor deposition (PECVD) layer, an undoped silicate glass (USG) layer, a fluorinated silicate glass (FSG) layer, a carbon doped oxide (CDO) layer, an organic silicate glass (OSG) layer, and a combination thereof.

Subsequently, a contact hole (not shown) is formed by etching a predetermined portion of the ILD 110 by performing a mask process and an etching process, exposing a portion of the substrate 100. Then, a plug material is formed over the above resulting substrate structure, filling the contact hole. Next, an etch-back process or a chemical mechanical polishing (CMP) process is performed to form a contact plug (not shown) buried in the contact hole.

Furthermore, the bottom electrode 120 is formed over the contact plug and the ILD 110. Herein, the bottom electrode 120 is formed by employing one selected from the group consisting of a sputtering method, an ALD method, and a CVD method. Preferably, the bottom electrode 120 is formed by employing one selected from the group consisting of doped polysilicon, TiN, Ru, RuO₂, Pt, Ir, IrO₂, RuTiN, HfN, and ZrN, using the ALD method.

Moreover, the dielectric structure 160 is formed over the bottom electrode 120 by forming the first dielectric layer 130 and the third dielectric layer 150, and forming the second dielectric layer 140 between the first dielectric layer 130 and the third dielectric layer 150. Herein, each of the first dielectric layer 130 and the third dielectric layer 150 is formed in a predetermined thickness that does not allow crystallization of the layers, i.e., in a thickness ranging from approximately 10 Å to approximately 70 Å. Preferably, each of the first dielectric layer 130 and the third dielectric layer 150 is formed with ZrO₂ in a thickness of approximately 40 Å. Also, the second dielectric layer 140 is formed in a thickness ranging from approximately 3 Å to approximately 10 Å by employing a non-crystallized dielectric layer. Preferably, the second dielectric layer 140 is formed with Al₂O₃ in a thickness of approximately 5 Å.

Next, a thermal process is performed to densify the dielectric structure 160. Herein, the non-crystallized dielectric structure 160 does not become crystallized during the thermal process, thus, leakage current generation can be reduced.

Subsequently, the upper electrode 170 is formed over the third dielectric layer 150. Herein, the upper electrode 170 is formed by employing one selected from the group consisting of a sputtering method, an ALD method, and a CVD method. Preferably, the upper electrode 170 is formed with one selected from the group consisting of doped polysilicon, TiN, Ru, RuO₂, Pt, Ir, IrO₂, and RuTiN, using the ALD method.

Hereinafter, a third embodiment of the present invention is described in detail.

A dielectric layer in accordance with the first embodiment of the present invention can be applied to an inter-poly dielectric (IPD) structure or an inter-poly oxide (IPO) structure in a non-volatile memory device. FIG. 8 is a cross-sectional view illustrating a non-volatile memory device formed in accordance with the third embodiment of the present invention, wherein the third embodiment is an example whereto the first embodiment of the present invention is applied.

The non-volatile memory device includes: a substrate 200 whereon a gate insulation layer 210 is formed; a floating gate 220 formed over a predetermined portion of the gate insulation layer 210; a dielectric structure 260 formed in accordance with the first embodiment of the present invention; and a control gate 270 formed over the dielectric structure 260. Herein, the dielectric structure 260 has a configuration substantially identical to that described in the first embodiment of the present invention. That is, the dielectric structure 260 includes a first dielectric layer 230 and a third dielectric layer 250, both formed with a substantially identical material, and a second dielectric layer 240 formed with a material different from that of the first dielectric layer 230 and the third dielectric layer 250. Herein, the second dielectric layer 240 is formed between the first dielectric layer 230 and the third dielectric layer 250. Since the dielectric structure 260 has the configuration substantially identical to that described in the first embodiment of the present invention, detailed descriptions with respect to configuration materials of the dielectric structure 260 are abridged herein.

Referring to FIG. 8, a method for fabricating the non-volatile memory device includes: forming the gate insulation layer 210 over the substrate 200; forming the floating gate 220 over the predetermined portion of the gate insulation layer 210; forming the dielectric structure 260 over the floating gate 220; and forming the control gate 270 over the dielectric structure 260.

In accordance with the specific embodiments of the present invention, crystallization of a dielectric structure can be prevented by: forming the first dielectric layer and the third dielectric layer, both made of a substantially identical material; and inserting the second dielectric layer having a crystallization rate lower than the first dielectric layer and the third dielectric layer, between the first dielectric layer and the third dielectric layer. Herein, the second dielectric layer is formed by employing a material different to that of the first dielectric layer and the third dielectric layer. Thus, the leakage current characteristic of a high-k dielectric layer having a high dielectric constant can be improved.

Furthermore, in accordance with the specific embodiments of the present invention, the dielectric capacity of the dielectric structure can be secured by satisfying the goal thickness of the final dielectric structure through: forming the first dielectric layer and the third dielectric layer in a predetermined thickness that does not allow crystallization of the layers; and forming the second dielectric layer between the first and the third dielectric layer, in a much smaller thickness than the first dielectric layer and the third dielectric layer.

Therefore, the dielectric capacity can be secured and the leakage current characteristic can be improved in the high-k dielectric layer. Furthermore, the dielectric capacity can be secured and the leakage current characteristic can be improved in the capacitor. Also, the leakage current characteristic of the non-volatile memory device can be improved.

The present application contains subject matter related to the Korean patent application No. KR 2005-0083692, filed in the Korean Patent Office on Sep. 8, 2005, the entire contents of which being incorporated herein by reference.

While the present invention has been described with respect to certain specific embodiments, it will be apparent to those skilled in the art that various changes and modifications may be made without departing from the spirit and scope of the invention as defined in the following claims.

What is claimed is:

1. A dielectric structure, comprising:
a first dielectric layer having a dielectric constant of approximately 25 or higher;
a second dielectric layer including a material having a crystallization rate lower than the first dielectric layer and formed over the first dielectric layer; and
a third dielectric layer including a material substantially identical to that of the first dielectric layer and formed over the second dielectric layer.

2. The dielectric structure of claim 1, wherein the first dielectric layer and the third dielectric layer are each formed in a predetermined thickness that does not allow crystallization of the first dielectric layer and the third dielectric layer.

3. The dielectric structure of claim 2, wherein the predetermined thickness ranges from approximately 10 Å to approximately 70 Å.

4. The dielectric structure of claim 2, wherein each of the first dielectric layer and the third dielectric layer includes one selected from the group consisting of zirconium dioxide (ZrO₂), hafnium oxide (HfO₂), lanthanum oxide (La₂O₃), and tantalum oxide (Ta₂O₅).

5. The dielectric structure of claim 4, wherein a total thickness of the first dielectric layer, the second dielectric layer, and the third dielectric layer ranges from approximately 70 Å to approximately 100 Å.

6. The dielectric structure of claim 5, wherein the ZrO₂ layer is formed in a thickness ranging from approximately 35 Å to approximately 45 Å.

7. The dielectric structure of claim 1, wherein the second dielectric layer includes a material having a crystallization rate lower than the first dielectric layer at a substantially identical temperature.

8. The dielectric structure of claim 1, wherein the second dielectric layer has a dielectric constant lower than the first dielectric layer.

9. The dielectric structure of claim 8, wherein the second dielectric layer includes a material crystallized at a temperature of approximately 900° C. or higher.

10. The dielectric structure of claim 1, wherein the second dielectric layer includes one selected from the group consisting of aluminum oxide (Al₂_{O}₃), silicon dioxide (SiO₂), and Ta₂O₅.

11. The dielectric structure of claim 1, wherein the second dielectric layer is formed in a thickness ranging from approximately 3 Å to approximately 10 Å.

12. A method for forming a dielectric structure, comprising:
forming a first dielectric layer having a dielectric constant of approximately 25 or higher;
forming a second dielectric layer over the first dielectric layer, the second dielectric layer having a crystallization rate lower than the first dielectric layer; and
forming a third dielectric layer over the second dielectric layer, the third dielectric layer including a material substantially identical to that of the first dielectric layer.

13. The method of claim 12, wherein the first dielectric layer and the third dielectric layer are each formed in a predetermined thickness that does not allow crystallization of the first dielectric layer and the third dielectric layer.

14. The method of claim 13, wherein the predetermined thickness ranges from approximately 10 Å to approximately 70 Å.

15. The method of claim 13, wherein each of the first dielectric layer and the third dielectric layer includes one selected from the group consisting of ZrO₂, HfO₂, La₂O₃, and Ta₂O₅.

16. The method of claim 15, wherein the ZrO₂ layer is formed in a thickness ranging from approximately 35 Å to approximately 45 Å.

17. The method of claim 13, wherein the forming of the first dielectric layer and the forming of the third dielectric layer comprises performing an atomic layer deposition (ALD) method or a chemical vapor deposition (CVD) method.

18. The method of claim 15, wherein the forming of the ZrO₂ layer uses one zirconium (Zr) source gas selected from the group consisting of Zr[N(CH₃)₂]₄, Zr[N(C₂H₅)(CH₃)]₄, Zr[N(C₂H₅)₂]₄, Zr(TMHD)₄, Zr(OiC₃H₇)₃(TMHD), Zr(OtBu)₄, and Zr(OtBu)(C₂H₅CH₃)₃.

19. The method of claim 17, wherein the forming of the first dielectric layer and the forming of the third dielectric layer each using the ALD method comprises employing an oxidation reaction gas selected from the group consisting of water (H₂O), ozone (O₃), and oxygen plasma.

20. The method of claim 17, wherein the forming of the first dielectric layer and the forming of the third dielectric layer each using the ALD method comprises employing one of nitrogen (N₂) and argon (Ar) as a purge gas for purging non-reacted gas.

21. The method of claim 12, wherein the forming of the second dielectric layer includes comprising a material having a crystallization rate lower than the first dielectric layer at a substantially identical temperature.

22. The method of claim 12, wherein the second dielectric layer has a dielectric constant lower than the first dielectric layer.

23. The method of claim 22, wherein the second dielectric layer includes a material crystallized at a temperature of approximately 900° C. or higher.

24. The method of claim 12, wherein the second dielectric layer includes one selected from the group consisting of Al₂O₃, SiO₂, and Ta₂O₅.

25. The method of claim 12, wherein the second dielectric layer is formed in a thickness ranging from approximately 3 Å to approximately 10 Å.

26. The method of claim 21, wherein the forming of the second dielectric layer comprises using an ALD method.

27. The method of claim 26, wherein the forming of the second dielectric layer using the ALD method comprises employing an oxidation reaction gas selected from the group consisting of H₂O, O₃, and oxygen plasma.

28. The method of claim 26, wherein the forming of the second dielectric layer using the ALD method comprises employing one of N₂ and Ar as a purge gas for purging non-reacted gas.

29. The method of claim 12, wherein each of the forming of the first dielectric layer, the second dielectric layer, and the third dielectric layer is performed at one substantially identical chamber.

30. The method of claim 29, wherein each of the forming of the first dielectric layer, the second dielectric layer, and the third dielectric layer at the substantially identical chamber is performed at a temperature ranging from approximately 200° C. to approximately 350° C.

31. The method of claim 12, wherein each of the forming of the first dielectric layer, the second dielectric layer, and the third dielectric layer is performed at different chambers, including a first chamber for forming the first and third dielectric layers and a second chamber for forming the second dielectric layer.

32. A semiconductor memory device, comprising:
a substrate on which a bottom electrode is formed;
a dielectric structure formed over the bottom electrode, wherein the dielectric structure includes: a first dielectric layer having a dielectric constant of approximately 25 or higher; a second dielectric layer including a material having a crystallization rate lower than the first dielectric layer and formed over the first dielectric layer; and a third dielectric layer including a material substantially identical to that of the first dielectric layer and formed over the second dielectric layer; and
an upper electrode formed over the dielectric structure.

33. The semiconductor memory device of claim 32, wherein the bottom electrode includes one selected from the group consisting of doped polysilicon, titanium nitride (TiN), ruthenium (Ru), ruthenium dioxide (RuO₂), platinum (Pt), iridium (Ir), iridium dioxide (IrO₂), RuTiN, hafnium mononitride (HfN), and zirconium mononitride (ZrN).

34. The semiconductor memory device of claim 32, wherein the upper electrode includes one selected from the group consisting of doped polysilicon, TiN, Ru, RuO₂, Pt, Ir, IrO₂, and RuTiN.

35. A method for fabricating a semiconductor memory device, comprising:
preparing a substrate whereon a bottom electrode is formed;
forming a dielectric structure over the bottom electrode, wherein the forming of the dielectric structure includes: forming a first dielectric layer having a dielectric constant of approximately 25 or higher; forming a second dielectric layer over the first dielectric layer, the second dielectric layer having a crystallization rate lower than the first dielectric layer; and forming a third dielectric layer over the second dielectric layer, the third dielectric layer having a material substantially identical to that of the first dielectric layer; and
forming an upper electrode over the dielectric structure.

36. The method of claim 35, wherein the bottom electrode includes one selected from the group consisting of doped polysilicon, TiN, Ru, RuO₂, Pt, Ir, IrO₂, RuTiN, HfN, and ZrN.

37. The method of claim 35, wherein the forming of the bottom electrode comprises employing one selected from the group consisting of a sputtering method, an ALD method, and a CVD method.

38. The method of claim 35, wherein the upper electrode includes one selected from the group consisting of doped polysilicon, TiN, Ru, RuO₂, Pt, Ir, IrO₂, and RuTiN.

39. The method of claim 35, wherein the forming of the upper electrode comprises employing one selected from the group consisting of a sputtering method, an ALD method, and a CVD method.

40. A semiconductor memory device, comprising:
a gate insulation layer formed over a substrate;
a floating gate formed over the gate insulation layer;
a dielectric structure formed over the floating gate, wherein the dielectric structure includes: a first dielectric layer having a dielectric constant of approximately 25 or higher; a second dielectric layer including a material having a crystallization rate lower than the first dielectric layer and formed over the first dielectric layer; and a third dielectric layer including a material substantially identical to that of the first dielectric layer and formed over the second dielectric layer; and
a control gate formed over the dielectric structure.

41. A method for fabricating a semiconductor memory device, comprising:
forming a gate insulation layer over a substrate;
forming a floating gate over the gate insulation layer;
forming a dielectric structure over the floating gate, wherein the forming of the dielectric structure includes: forming a first dielectric layer having a dielectric constant of 25 or higher; forming a second dielectric layer over the first dielectric layer, the second dielectric layer having a crystallization rate lower than the first dielectric layer; and forming a third dielectric layer over the second dielectric layer, the third dielectric layer having a material substantially identical to that of the first dielectric layer; and
forming a control gate over the dielectric structure.
